(19) United States
(12) Patent Application Publication
(10) Pub. No.: US 2012/0045723 A1
(43) Pub. Date: Feb. 23, 2012

(54) VIBRATION ISOLATION DEVICE, EXPOSURE APPARATUS, AND DEVICE MANUFACTURING METHOD USING SAME

(75) Inventors: Ryo NAWATA, Utsunomiya-shi (JP); Katsumi ASADA, Utsunomiya-shi (JP)

(73) Assignee: CANON KABUSHIKI KAISHA, Tokyo (JP)

(21) Appl. No.: 13/207,519

(22) Filed: Aug. 11, 2011

(30) Foreign Application Priority Data
Aug. 20, 2010 (JP) 2010-184616

(51) Int. Cl. G03B 27/00; F16M 13/00; G03F 7/20; F16F 7/00

(52) U.S. Cl. 430/325; 248/550; 355/18

(57) ABSTRACT

The vibration isolation device of the present invention includes a first position feedback control system including a reference body system that is fixed to an object to be isolated from vibration and includes a reference body; a first driving unit that drives the object with respect to a base; and a first compensator that calculates a command value to the first driving unit based on position information obtained from the reference body system. Also, the reference body system includes a second position feedback control system including a second driving unit that drives the reference body with respect to the object; a first measuring unit that measures the position of the reference body relative to the object; and a second compensator that calculates a command value to the second driving unit based on position information obtained from the first measuring unit. Here, the second compensator is a PD compensator.

### BACKGROUND OF THE INVENTION

1. Field of the Invention

The present invention relates to a vibration isolation device, an exposure apparatus, and a device manufacturing method using the same.

2. Description of the Related Art

An exposure apparatus is an apparatus that transfers a pattern of an original (reticle or mask) onto a photosensitive substrate (e.g., wafer, glass plate, or the like, where the surface thereof is coated with a resist layer) via a projection optical system in a lithography process of a manufacturing process for a semiconductor device, a liquid crystal display device, or the like. In the exposure apparatus which is involved in the ultra-fining of a pattern, the vibration transmitted from the floor upon which the exposure apparatus stands to the apparatus body may cause degradation of overlapping exposure (overlay) accuracy, exposure image accuracy, and the like. Accordingly, the exposure apparatus is generally arranged via a vibration isolation device for reducing the influence of floor vibration. Likewise, for a highly accurate measuring apparatus, an electron beam plotting apparatus, a processing apparatus employing imprint technology, or the like, a method for supporting the main body thereof by a vibration isolation device is employed.

The conventional vibration isolation device uses a gas spring inserted between the vibration isolation table and the floor. In addition, to increase the damping characteristic of the vibration isolation device, the velocity feedback control is performed using an acceleration sensor arranged on the vibration isolation table and an actuator interposed between the vibration isolation table and the floor. However, the velocity feedback control may increase the damping characteristic of the vibration isolation device, but may not lower the natural frequency of the vibration isolation device. Hence, Japanese Patent Laid-Open No. 2007-240396 discloses a vibration isolation device in which a pendulum (reference body) supported by a spring member extended from a frame is arranged on a vibration isolation table and measures relative displacement between the frame and the pendulum to thereby feedback-control the position of the relative displacement to an actuator for driving the vibration isolation table.

In general, when a vibration isolation device feedback-controls the position of a vibration isolation table with respect to a reference body supported by an elastic system having a low natural frequency, the vibration isolation device may isolate the vibration at a frequency lower than the natural frequency defined by the mass of the vibration isolation table and the rigidity of the gas spring. As a means for realizing an elastic system having a low natural frequency, the reference body is typically supported by a spring member or a pendulum. In this case, in order to achieve a considerably low natural frequency of the reference body, the weight of the reference body, the rigidity of the spring, the length of the pendulum, and the like need to be mechanically adjusted. However, when the reference body is arranged on the vibration isolation table, it is difficult to realize the reference body having a considerably low natural frequency, for example, 1 Hz or lower due to installation space.

In general, as a compensator for a position feedback control system, a PID compensator is used. In this case, firstly, the relative position between the reference body of which the position is feedback-controlled by the PID compensator and the vibration isolation table is measured. When the relative position is position feed back to an actuator for driving the vibration isolation table, the integrator provided in the PID compensator of the reference body couples with the rigidity of the gas spring in the vibration isolation device, and thus, a sharp peak occurs in the transfer function from the base to the vibration isolation table. Therefore, when the sharp peak is excited due to floor vibration or the like, the vibration isolation table may oscillate significantly.

### SUMMARY OF THE INVENTION

The present invention has been made in view of the aforementioned circumstances, and provides a vibration isolation device that exhibits excellent vibration isolation performance even at a low frequency.

In view of the foregoing, according to an aspect of the present invention, a vibration isolation device that isolates the vibration of an object to be isolated from vibration supported on a base is provided that includes a first position feedback control system including a reference body system that is fixed to the object to be isolated from vibration and includes a reference body; a first driving unit that drives the object to be isolated from vibration with respect to the base; and a first compensator that calculates a command value for the first driving unit based on position information obtained from the reference body system, wherein the reference body system includes a second position feedback control system including a second driving unit that drives the reference body with respect to the object to he isolated from vibration; a first measuring unit that measures the position of the reference body relative to the object to be isolated from vibration; and a second compensator that calculates a command value to the second driving unit based on position information obtained from the first measuring unit, and wherein the second compensator is a PD compensator.

According to the present invention, a vibration isolation device that exhibits excellent vibration isolation performance even at a low frequency may be provided.

Further features of the present invention will become apparent from the following description of exemplary embodiments with reference to the attached drawings.

### BRIEF DESCRIPTION OF THE DRAWINGS

FIG. 1A is a schematic diagram illustrating a reference body system that is arranged in the horizontal direction according to an embodiment of the present invention.

FIG. 1B is a schematic diagram illustrating a first reference body system that is arranged in the vertical direction according to an embodiment of the present invention.

FIG. 1C is a schematic diagram illustrating a second reference body system that is arranged in the vertical direction according to an embodiment of the present invention.

FIG. 2 is a schematic view illustrating the configuration of a vibration isolation device according to a first embodiment.

FIG. 3 is a Bode plot diagram of the transfer function H from a base to a vibration isolation table.

FIG. 4A is a block diagram of the transfer function H from the base to the vibration isolation table.

FIG. 4B is a block diagram of the transfer function H from the base to the vibration isolation table.

FIG. 4C is a block diagram of the transfer function H from the base to the vibration isolation table.

FIG. 5 is a Bode plot diagram of the transfer function H and the transfer function G₁×H₁.

FIG. 6A is a pole arrangement diagram of the transfer function H_{Apid}.

FIG. 6B is a pole arrangement diagram of the transfer function H_{Apd}.

FIG. 7A is a schematic view illustrating the configuration of a vibration isolation device according to a second embodiment.

FIG. 7B is a schematic view illustrating the configuration of a vibration isolation device according to a third embodiment.

FIG. 7C is a schematic view illustrating the configuration of a vibration isolation device according to a fourth embodiment.

FIG. 7D is a schematic view illustrating the configuration of a vibration isolation device according to a fifth embodiment.

FIG. 8A is a Bode plot diagram of the transfer function H₂ from the base to the vibration isolation table.

FIG. 8B is a Bode plot diagram of the transfer function H₃ from the base to the vibration isolation table.

FIG. 9A is a block diagram of the transfer function H₂ from the base to the vibration isolation table.

FIG. 9B is a block diagram of the transfer function H_{A2} from the base to the vibration isolation table.

FIG. 9C is a block diagram of the transfer function H₃ from the base to the vibration isolation table.

FIG. 9D is a block diagram of the transfer function H_{A3} from the base to the vibration isolation table.

FIG. 10A is a Bode plot diagram of the transfer function H₄ from the base to the vibration isolation table.

FIG. 10B is a Bode plot diagram of the transfer function H₅ from the base to the vibration isolation table.

FIG. 11 is a schematic view illustrating the configuration of a vibration isolation device according to an eighth embodiment.

FIG. 12 is a block diagram illustrating a method for controlling a vibration isolation device according to the eighth embodiment.

FIG. 13 is a schematic view illustrating the configuration of a vibration isolation device according to a ninth embodiment.

FIG. 14A is a schematic view illustrating the configuration of a reference body system according to the ninth embodiment.

FIG. 14B is a bottom plan view illustrating a reference body facing a base in a reference body system according to the ninth embodiment.

FIG. 14C is a top plan view illustrating a base facing a reference body in a reference body system according to the ninth embodiment.

FIG. 15 is a block diagram illustrating a method for controlling a vibration isolation device according to the ninth embodiment.

FIG. 16 is a schematic view illustrating the configuration of an exposure apparatus according to an embodiment of the present invention.

### DESCRIPTION OF THE EMBODIMENTS

Hereinafter, preferred embodiments of the present invention will now be described with reference to the accompanying drawings.

### First Embodiment

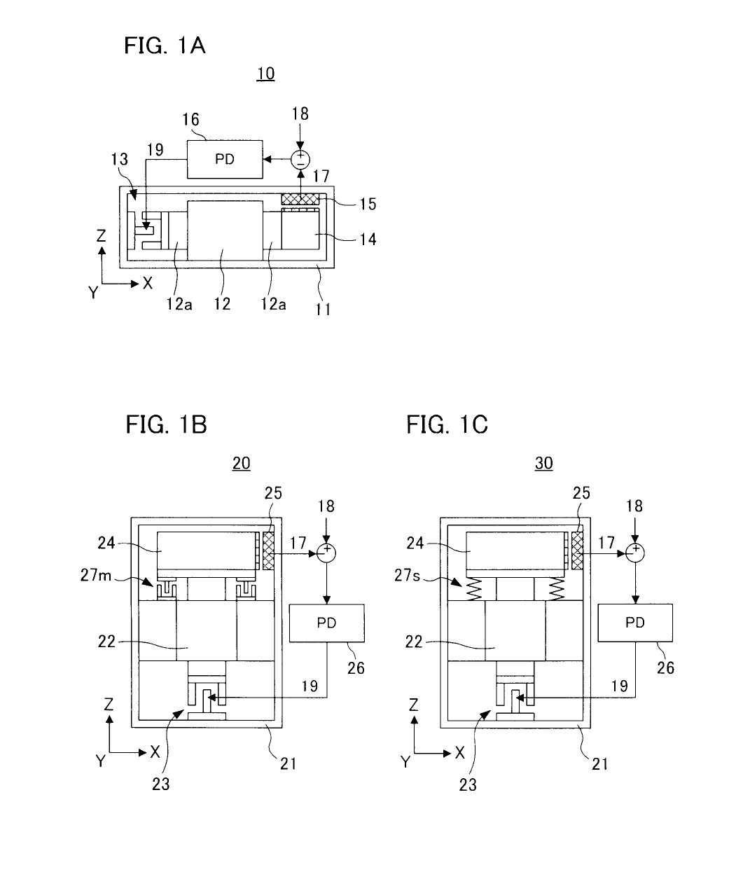

Firstly, a description will be given of a reference body system to be employed for a vibration isolation device according to an embodiment of the present invention. FIGS. 1A to 1C are schematic views illustrating the configuration of a reference body system for a single axis measurement to he employed for the vibration isolation device of the present invention. In particular, FIG. 1A is a schematic diagram illustrating a reference body system 10 that is arranged in the horizontal direction, FIG. 1B is a schematic diagram illustrating a first reference body system 20 that is arranged in the vertical direction, and FIG. 1C is a schematic diagram illustrating a second reference body system 30 that is arranged in the vertical direction. In the following drawings, a description will be given by taking the Z-axis in the vertical direction of the reference body system, and the X-axis and the Y-axis in the horizontal direction normal to the Z-axis.

Firstly, as shown in FIG. 1A, the reference body system 10 for the horizontal direction includes a reference body base 11, a linear guide 12, an actuator 13 provided consecutively to the linear guide 12, a reference body 14 supported by the linear guide 12, and a position sensor 15. The linear guide 12 is a guide unit that is rigidly fixed to the reference body base 11 so as to guide a linear slider 12a. For example, as the linear guide 12, an air guide, an electromagnetic guide, or the like may be employed. For the linear slider 12a that is movable relative to the fixing section of the linear guide 12, the actuator 13 is arranged at one end thereof and the reference body 14 is arranged at the other end thereof. The actuator 13 is a driving unit (second driving unit) that employs, for example, a voice coil motor or the like. The reference body 14 is an object that is supported by the reference body base 11 with a natural frequency lower than that of the object to be isolated from vibration so as to allow the position of the object to be isolated from vibration to be tracked to thereby enhance vibration isolation performance. Although, in the present embodiment, the reference body 14 is formed separately from the linear slider 12a, the reference body 14 may be integrally formed with the linear slider 12a. The position sensor 15 is a measuring unit (first measuring unit) that measures the relative position between the reference body base 11 and the reference body 14. In order to reduce the measurement error of the position sensor 15, the linear guide 12 is arranged as far as possible parallel to the reference body base 11.

Furthermore, the reference body system 10 includes a compensator 16, which is electrically connected to the actuator 13 and the position sensor 15, as part of a control system. Here, the control system is a control unit (second position feedback control system) that feedback-controls the position of the reference body 14 relative to the reference body base 11 based on position information 17 obtained by the position sensor 15. The compensator 16 is a unit (second compensator) that calculates a control signal 19, which is a command value applied to the actuator 13, based on the position information 17 and a preset target value 18. In particular, in the present embodiment, a PD compensator is employed as the compensator 16. Formula 1 is a formula indicative of the transfer function for the PD compensator, where reference symbol Mᵣ denotes the mass of the reference body 14, reference symbol W_{cr} denotes the crossover frequency of the feedback-control of the position of the reference body 14, reference symbol W_{cr} denotes the break frequency of a differentiator, and reference symbol s is a complex number (Laplace operator).

$${M}_{r} \cdot {W}_{cr} \cdot {W}_{dr} ( 1 + \frac{s}{{W}_{dr}} ) \qquad [ Formula 1 ]$$

Next, as shown in FIG. 1B and FIG. 1C, each of first and second reference body systems 20 and 30 for the vertical direction includes a reference body base 21, a linear guide 22, an actuator 23, a reference body 24, a position sensor 25, and a compensator 26. Each of the reference body systems 20 and 30 is in a state in which the reference body system 10 is rotated by 90 degrees. Since the components of each of the first and second reference body systems 20 and 30 correspond to the components of the reference body system 10 and provide the same effects as those of the reference body system 10, the explanation thereof will be omitted. Here, a description will be given of an own-weight compensation unit 27 for compensating the own-weight of the reference body 24, which is the feature of the reference body systems 20 and 30 for the vertical direction. The own-weight compensation unit 27 is a compensation unit configured to compensate the own weight of a mobile unit including the reference body 24. Examples of the own-weight compensation unit 27 include a permanent magnet or an own-weight compensation spring. Firstly, as shown in FIG. 1B, the first reference body system 20 employs a permanent magnet 27m as the own-weight compensation unit 27. In this case, the permanent magnet 27m compensates the own-weight of the reference body 24 by generating a repulsive force substantially balancing with a gravity force of the reference body 24. On the other hand, as shown in FIG. 1C, the second reference body system 30 employs an own-weight compensation spring 27s as the own-weight compensation unit 27. The own-weight compensation spring 27s also compensates the own-weight of the reference body 24 by generating a repulsive force substantially balancing with a gravity force of the reference body 24. When the own-weight compensation spring 27s is employed as shown in FIG. 1C, the weight of the mobile units including the reference body 24 and the natural frequency defined by the spring rigidity of the own-weight compensation spring 27s are set so as to be lower than the crossover frequency of the feedback-control of the position of the reference body 24.

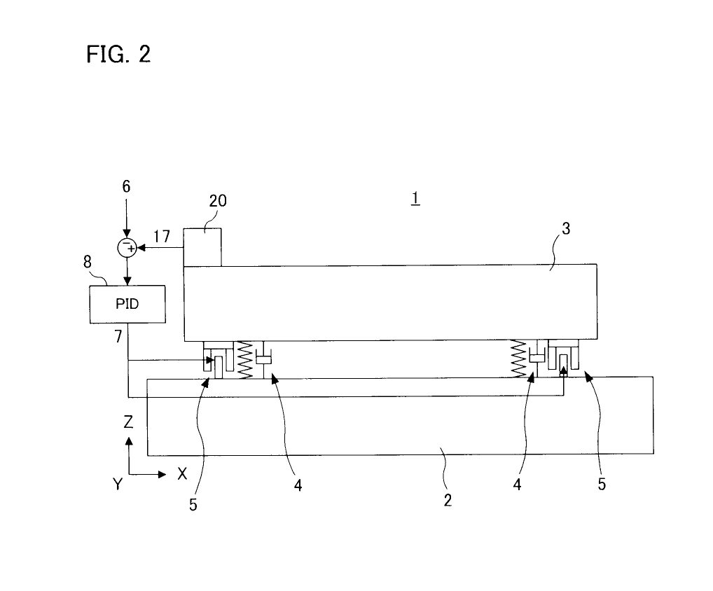

Next, a description will be given of a vibration isolation device according to the present embodiment employing the reference body system. FIG. 2 is a schematic view illustrating the configuration of a vibration isolation device according to the present embodiment. In the present embodiment, a description will be given on the assumption that a vibration isolation device is intended to isolate vibration in the vertical direction and the first reference body system 20 for the vertical direction is employed as shown in FIG. 2. Firstly, a vibration isolation device 1 includes a base 2 and a vibration isolation table 3 that is an object to be isolated from vibration, which is supported by the base 2. A plurality of gas springs (air springs) 4 serving as vibration isolation units and a plurality of actuators 5 serving as first driving units are arranged between the base 2 and the vibration isolation table 3. The vibration isolation device 1 further includes the reference body system 20 provided on the vibration isolation table 3. The reference body system 20 is rigidly fixed to the vibration isolation table 3, and thus, the position information 17 for the reference body system 20 is the relative position information between the reference body 24 and the vibration isolation table 3. The control system (first position feedback control system) feedbacks the position information 17 to the actuator 5 to thereby feedback-control the position of the vibration isolation table 3 relative to the reference body 24. Furthermore, the vibration isolation device 1 includes a compensator (first compensator) 8 that calculates a control signal 7 to be sent to the actuator 5 based on the position information 17 and a target value 6 transmitted from the control device in advance. In particular, in the present embodiment, a PID compensator is employed as the compensator 8. Formula 2 is a formula indicative of the transfer function for the PID compensator, where reference symbol Mⱼ denotes the mass of the vibration isolation table 3, reference symbol W_{cj} denotes the crossover frequency of the feedback-control of the position of the vibration isolation table 3, reference symbol W_{dj} denotes the break frequency of a differentiator, and reference symbol Wᵢⱼ denotes the break frequency of an integrator.

$${M}_{j} \cdot {W}_{cj} \cdot {W}_{dj} ( 1 + \frac{s}{{W}_{dj}} ) ( 1 + \frac{{W}_{ij}}{s} ) \qquad [ Formula 2 ]$$

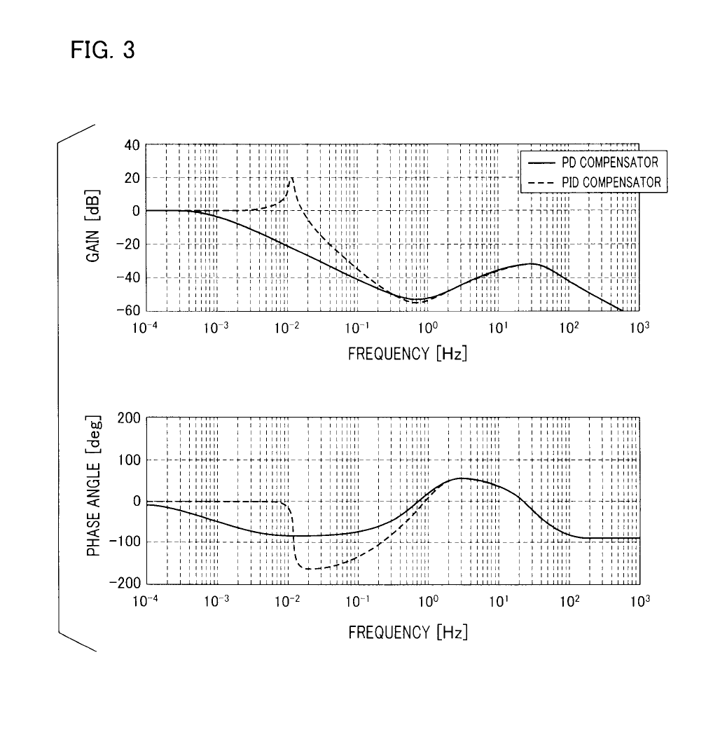

Next, a case where a PD compensator is employed as the compensator 26 of the reference body system 20, as in the present embodiment, is compared to an exemplary case where a PID compensator is employed as the same. FIG. 3 is a Bode plot diagram of the transfer function H from the base 2 to the vibration isolation table 3 for a case where a PD compensator is employed as the compensator 26 and a case where a PID compensator is employed as the same. In FIG. 3, the horizontal axis represents frequency (Hz), and the vertical axis represents the gain (dB) of the transfer function H in the upper figure and represents the phase angle (deg) of the transfer function H in the lower figure. The vertical axis and the horizontal axis are similarly applied to the following Bode plot diagrams. As shown in FIG. 3, when a PID compensator is employed, a sharp peak occurs around 0.01 Hz. In contrast, when a PD compensator is employed as in the present embodiment, such a vibration isolation device exhibits excellent vibration isolation performance even at a low frequency without producing a sharp peak. In particular, the vibration isolation table 3 is isolated from vibration at a frequency lower than the natural frequency defined by the mass Mⱼ of the vibration isolation table 3 and the rigidity k of the gas spring. Hereinafter, a lower-limit frequency that can be isolated from vibration by feedback-controlling the position of the vibration isolation table 3 relative to the reference body 24 is referred to as a “vibration isolation frequency”.

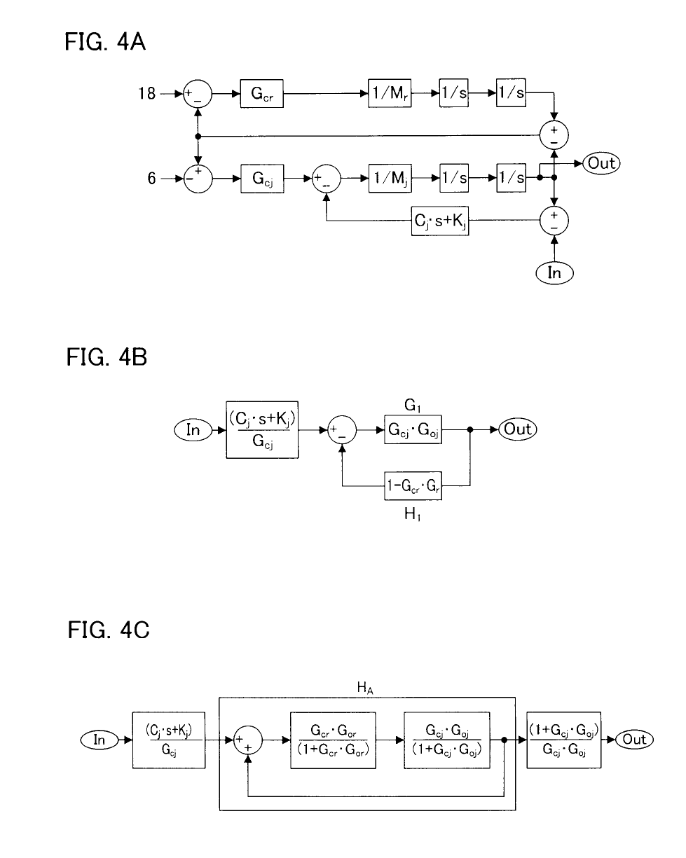

Next, a description will be given of a method for calculating the vibration isolation frequency. FIGS. 4A to 4c are block diagrams illustrating the transfer function H from the base 2 to the vibration isolation table 3. In FIG. 4, reference symbol G_{cr} denotes the compensator 26, reference symbol Gₒ denotes the compensator 8 for the vibration isolation table 3, reference symbol kⱼ denotes the rigidity of the gas spring, and reference symbol Cⱼ denotes the viscosity of the gas spring. Here, when 1/(Mᵣ×s²+G_{cr}) is replaced by Gr and 1/(M×s²+C×s+Kⱼ) is replaced by Gₒⱼ, the block diagram shown in FIG. 4A can be modified into the block diagram shown in FIG. 4B. Furthermore, given that the product of G_{cj}×Gₒⱼ is represented by G₁ and the product of 1−G_{cr}×Gᵣ is represented by H₁, the transfer function H is represented as shown in Formula 3 when the product of G₁×H₁>1, whereas the transfer function H is represented as shown in Formula 4 when the product of G₁×H₁<1.

$$\begin{matrix}H = \frac{{C}_{j} \cdot s + {K}_{j}}{{G}_{cj}} \cdot \frac{1}{1 - {G}_{cr} \cdot {G}_{r}} & [ Formula 3 ] \\ H = \frac{{C}_{j} \cdot s + {K}_{j}}{{G}_{cj}} \cdot {G}_{cj} \cdot {G}_{oj} = \frac{{C}_{j} \cdot s + {K}_{j}}{{M}_{j} \cdot {s}^{2} + {C}_{j} \cdot s + {K}_{j}} & [ Formula 4 ]\end{matrix}$$

Here, the right side of Formula 4 is the transfer function, which is transferred from the base 2 to the vibration isolation table 3, related to the vibration isolation table 3 when the position-feedback-control is not performed. In other words, Formula 3 and Formula 4 indicate that the vibration isolation frequency of the vibration isolation table 3 that provides position-feedback-control is the crossover frequency of the transfer function (G₁×H₁). Hence, when the crossover frequency of the transfer function (G₁×H₁) is calculated, the vibration isolation frequency of the vibration isolation table 3 that provides position-feedback-control may be determined. Since the vibration isolation frequency is low frequency, the transfer function (G₁×H₁) is represented by Formula 5 when only the factors that affect low frequency are taken into account.

$$\begin{matrix}{G}_{1} \cdot {H}_{1} = {G}_{cj} \cdot {G}_{oj} ( 1 - {G}_{cr} \cdot {G}_{r} ) \\ = ( {M}_{j} \cdot {W}_{cj} \cdot {W}_{dj} ) \frac{s + {W}_{ij}}{s} \cdot \frac{1}{{K}_{j}} \cdot \\ \{ 1 - ( {M}_{j} \cdot {W}_{cj} \cdot {W}_{dj} ) \cdot \frac{1}{{M}_{r} \cdot ( {s}^{2} + {W}_{cr} \cdot {W}_{dr} )} \}\end{matrix} \qquad [ Formula 5 ]$$

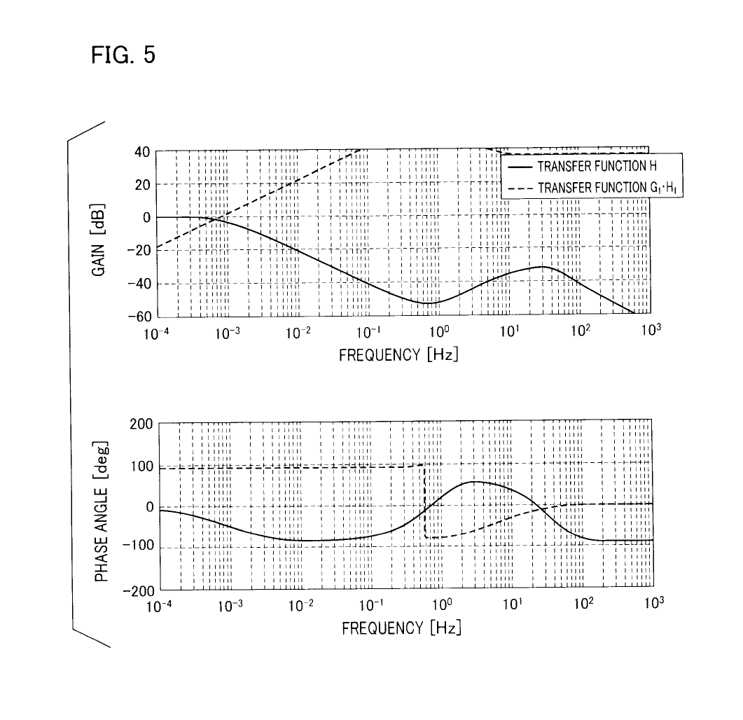

For comparison, FIG. 5 shows a Bode plot diagram of the transfer function H and the transfer function (G₁×H₁) represented by Formula 5. As shown in FIG. 5, it is understood that the vibration isolation frequency of the vibration isolation table 3 subject to position-feedback-control is the crossover frequency of the transfer function (G₁×H₁). In other words, the crossover frequency of the transfer function (G₁×H₁) represented by Formula 5 is a solution obtained when the right side of Formula 5 is set to 1, and the value of the solution is represented by Formula 6. Also, Formula 6 may be approximated as in Formula 7 based on the relationship of Mⱼ×W_{cj}×W_{dj}>>Kⱼ.

$$\begin{matrix}s = \frac{\begin{matrix}- {M}_{j} \cdot {W}_{cj} \cdot {W}_{dj} \cdot {W}_{ij} + \\ \sqrt{\begin{matrix}{( {M}_{j} \cdot {W}_{cj} \cdot {W}_{dj} \cdot {W}_{ij} )}^{2} + \\ 4 ( {M}_{j} \cdot {W}_{cj} \cdot {W}_{dj} - {K}_{j} ) ( {K}_{j} \cdot {W}_{cr} \cdot {W}_{dr} )\end{matrix}}\end{matrix}}{2 ( {M}_{j} \cdot {W}_{cj} \cdot {W}_{dj} - {K}_{j} )} & [ Formula 6 ] \\ s = \frac{{W}_{cr} \cdot {W}_{dr}}{{W}_{cj} \cdot {W}_{dj}} \cdot \frac{1}{{W}_{ij}} \cdot \frac{{K}_{j}}{{M}_{j}} & [ Formula 7 ]\end{matrix}$$

It should be noted that the vibration isolation frequency of the vibration isolation table 3 subject to position-feedback-control must be lower than the natural frequency that is defined by the mass Mⱼ of the vibration isolation table 3 and the rigidity Kⱼ of the gas spring 4. Thus, the relational formula represented by Formula 8 needs to be satisfied.

$$\frac{{W}_{cr} \cdot {W}_{dr}}{{W}_{cj} \cdot {W}_{dj}} \cdot \frac{1}{{W}_{ij}} \cdot \frac{{K}_{j}}{{M}_{j}} < \sqrt{\frac{{K}_{j}}{{M}_{j}}} \qquad [ Formula 8 ]$$

Next, the reasons that a sharp peak occurs when a PID compensator is employed as the compensator 26 of the reference body system 20 whereas a sharp peak does not occur when a PD compensator is employed as in the present embodiment, as shown in FIG. 3, will be described below. Firstly, when the block diagram shown in FIG. 4A is transformed, the resulting block diagram is as shown in FIG. 4C. Here, when the block diagram enclosed within the frame shown in FIG. 4C is defined as the transfer function H_{A}, and is further transformed, the transfer function H_{A} is represented by Formula 9.

$${H}_{A} = \frac{{G}_{cj} \cdot {G}_{oj} \cdot {G}_{cr} \cdot {G}_{or}}{1 + {G}_{cj} \cdot {G}_{oj} + {G}_{cr} \cdot {G}_{or}} \qquad [ Formula 9 ]$$

Firstly, assume the case where a PID compensator is employed as the compensator 26. In this case, the transfer function H_{A} is represented by the transfer function H_{Apid}. When a PID compensator is employed as the compensator 26, the transfer function of the compensator 26 is represented by Formula 10, provided that reference symbol Wᵢᵣ denotes the break frequency of the integrator of the reference body 14.

$${G}_{cr} = {M}_{r} \cdot {W}_{cr} \cdot {W}_{dr} ( 1 + \frac{s}{{W}_{dr}} ) ( 1 + \frac{{W}_{iv}}{s} ) \qquad [ Formula 10 ]$$

Here, since a peak occurs in the transfer function H at a low frequency, reference symbols G_{cj}, Gₒⱼ, G_{cr}, and Gₒᵣ are represented by Formula 11, Formula 12, Formula 13, and Formula 14, respectively, when only the factors that affect low frequency are taken into account.

$$\begin{matrix}{G}_{cj} = ( {M}_{j} \cdot {W}_{cj} \cdot {W}_{dj} ) \frac{s + {W}_{ij}}{s} & [ Formula 11 ] \\ {G}_{oj} = \frac{1}{{K}_{j}} & [ Formula 12 ] \\ {G}_{cr} = ( {M}_{r} \cdot {W}_{cr} \cdot {W}_{dr} ) \frac{s + {W}_{ir}}{s} & [ Formula 13 ] \\ {G}_{or} = \frac{1}{{M}_{r} \cdot {s}^{2}} & [ Formula 14 ]\end{matrix}$$

Here, when Formulae 11 to Formula 14 are substituted for Formula 9, the transfer function H_{Apid} is represented by Formula 15, provided that the relationships MWⱼ=Mⱼ×W_{cj}×Wₒⱼ and MWᵣ=Mᵣ×W_{cr}×Wₒᵣ are satisfied.

$${H}_{Apid} = \frac{\begin{matrix}{MW}_{j} \cdot {MW}_{r} \cdot {s}^{2} + {MW}_{j} \cdot M {W}_{r} ( {W}_{ij} + {W}_{ir} ) s + \\ {MW}_{j} \cdot {MW}_{r} \cdot {W}_{ij} \cdot {W}_{ir}\end{matrix}}{s \{ \begin{matrix}( {K}_{j} \cdot {M}_{r} + {MW}_{j} \cdot {M}_{r} ) {s}^{3} + {MW}_{j} \cdot {M}_{r} \cdot {W}_{ij} \cdot {s}^{2} + \\ {MW}_{r} \cdot {K}_{j} \cdot s + {MW}_{r} \cdot {K}_{j} \cdot {W}_{ir}\end{matrix} \}} \qquad [ Formula 15 ]$$

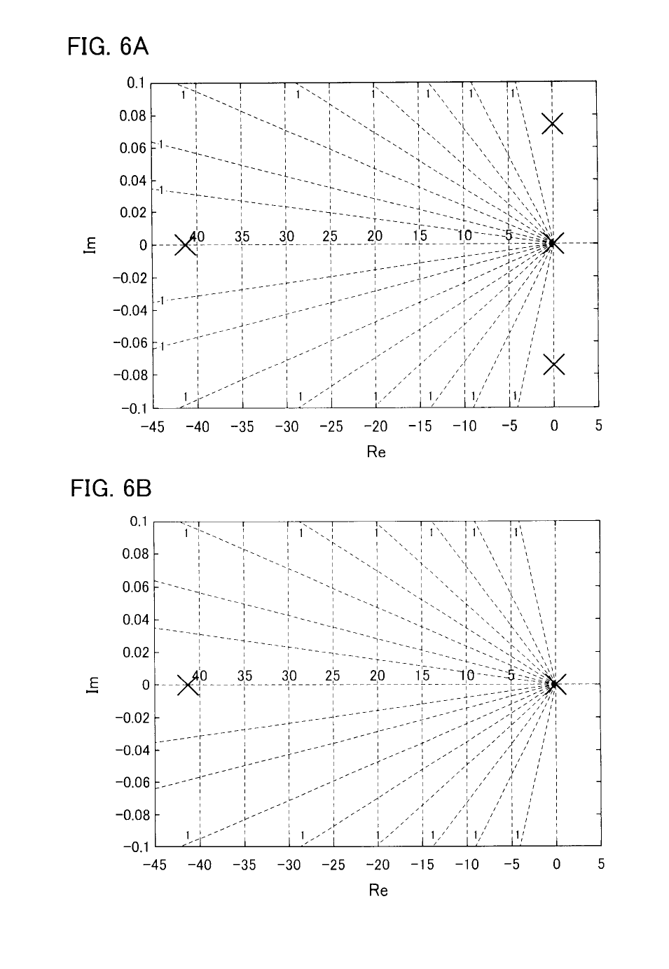

FIG. 6A is a pole arrangement diagram of the transfer function H_{Apid} obtained when the values shown in Table 1 are substituted for Mⱼ, Kⱼ, W_{cj}, W_{dj}, Wᵢⱼ, Mᵣ, W_{cr}, W_{dr}, and Wᵢᵣ in Formula 15 described above. In FIG. 6A, the vertical axis represents the imaginary axis and the horizontal axis represents the real axis. The characteristic equation of the transfer function H_{Apid} has conjugate complex number solutions as shown by the “X” mark in FIG. 6A, and more specifically, has two real number solutions (one of them is zero) and two conjugate complex number solutions as represented by Formula 16.

TABLE 1

| Symbol | Value | Unit |
|---|---|---|
| Mⱼ | 500.00 | Kg |
| Kⱼ | 177650.00 | N/m |
| W_{cj} | 251.33 | rad/s |
| W_{dj} | 83.78 | rad/s |
| Wᵢⱼ | 41.89 | rad/s |
| Mᵣ | 0.67 | Kg |
| W_{cr} | 6.28 | rad/s |
| W_{dr} | 2.09 | rad/s |
| Wᵢᵣ | 1.05 | rad/s |

$$s \{ ( {K}_{j} \cdot {M}_{r} + {MW}_{j} \cdot {M}_{r} ) {s}^{3} + {MW}_{j} \cdot {M}_{r} \cdot {W}_{ij} \cdot {s}^{2} + {MW}_{r} \cdot {K}_{j} \cdot s + {MW}_{r} \cdot {K}_{j} \cdot {W}_{ir} \} = s ( s + a ) ( s - ( - b - ic ) ) ( s - ( - b + ic ) ) = 0 \qquad [ Formula 16 ]$$

In this way, when a PID compensator is employed as the compensator 26 of the reference body system 20, the break frequency Wᵢᵣ of the integrator of the PID compensator, the rigidity Kⱼ of the gas spring 4, Mᵣ, W_{cr}, and W_{dr} are coupled to each other, and thus, the characteristic equation of the transfer function H_{Apid} have the conjugate complex number solutions. In other words, the damping ratio is in the range of 0<ζ<1 due to having conjugate complex number solutions, and thus the vibration isolation table 3 is in a deficient damping state. Thus, a sharp peak occurs in the transfer function H from the base 2 to the vibration isolation table 3.

Next, assume the case where a PD compensator is employed as the compensator 26 according to the present embodiment. In this case, the transfer function H_{A} is represented by the transfer function H_{Apd}. Since a sharp peak occurs at a low frequency in a case in which the PID compensator is employed, G_{cr} (the compensator 26) is represented by Formula 17 when only the factors that affect low frequency are taken into account. Furthermore, as in Formula 15, when Formula 11, Formula 12, Formula 14, and Formula 17 are substituted for Formula 9, the transfer function H_{Apd} in this case is represented by Formula 18.

$$\begin{matrix}{G}_{cr} = {M}_{r} \cdot {W}_{cr} \cdot {W}_{dr} & [ Formula 17 ] \\ {H}_{Apd} = \frac{{MW}_{j} \cdot {MW}_{r} ( s + {W}_{ij} )}{s \{ \begin{matrix}( {K}_{j} \cdot {M}_{r} + {MW}_{j} \cdot {M}_{r} ) {s}^{2} + \\ {MW}_{j} \cdot {M}_{r} \cdot {W}_{ij} \cdot s + {MW}_{r} \cdot {K}_{j}\end{matrix} \}} & [ Formula 18 ]\end{matrix}$$

FIG. 6B is a pole arrangement diagram of the transfer function H_{Apd} obtained when the values shown in Table 2 are substituted for Mⱼ, Kⱼ, W_{cj}, W_{dj}, Wᵢⱼ, Mᵣ, W_{cr}, and W_{dr} in Formula 18 described above. FIG. 6B corresponds to the pole arrangement diagram shown in FIG. 6A. As shown in FIG. 6B, the characteristic equation of the transfer function H_{Apd} does not have a conjugate complex number solution, but has three real number solutions (one of them is zero) as represented by Formula 19.

TABLE 2

| Symbol | Value | Unit |
|---|---|---|
| Mⱼ | 500.00 | Kg |
| Kⱼ | 177650.00 | N/m |
| W_{cj} | 251.33 | rad/s |
| W_{dj} | 83.78 | rad/s |
| Wᵢⱼ | 41.89 | rad/s |
| Mᵣ | 0.67 | Kg |
| W_{cr} | 6.28 | rad/s |
| W_{dr} | 2.09 | rad/s |

$$s \{ ( {K}_{j} \cdot {M}_{r} + {MW}_{j} \cdot {M}_{r} ) {s}^{2} + {MW}_{j} \cdot {M}_{r} \cdot {W}_{ij} \cdot {s}^{2} + {MW}_{r} \cdot {K}_{j} \} = s ( s + {a}^{′} ) ( s + {b}^{′} ) = 0 \qquad [ Formula 19 ]$$

In this way, when a PD compensator is employed as the compensator 26 of the reference body system 20, the characteristic equation of the transfer function H_{Apd} does not have any conjugate complex number solution. In other words, the vibration isolation table 3 is in a critical damping state or in an excessive damping state, the occurrence of a sharp peak in the transfer function H from the base 2 to the vibration isolation table 3 can be suppressed.

As described above, according to the present invention, since a PD compensator is employed as the compensator of the reference body system and is controlled by the position feedback control system, a reference body having a considerably low natural frequency may be realized simply by adjusting the gain of the position-feedback. Thus, the vibration isolation device 1 employing the reference body system may exhibit excellent vibration isolation performance even at a low frequency. While a description has been given by taking an example where the vibration isolation device 1 is arranged in the vertical direction, the present invention is applicable to the case where the vibration isolation device 1 is arranged in the horizontal direction as well.

### Second Embodiment

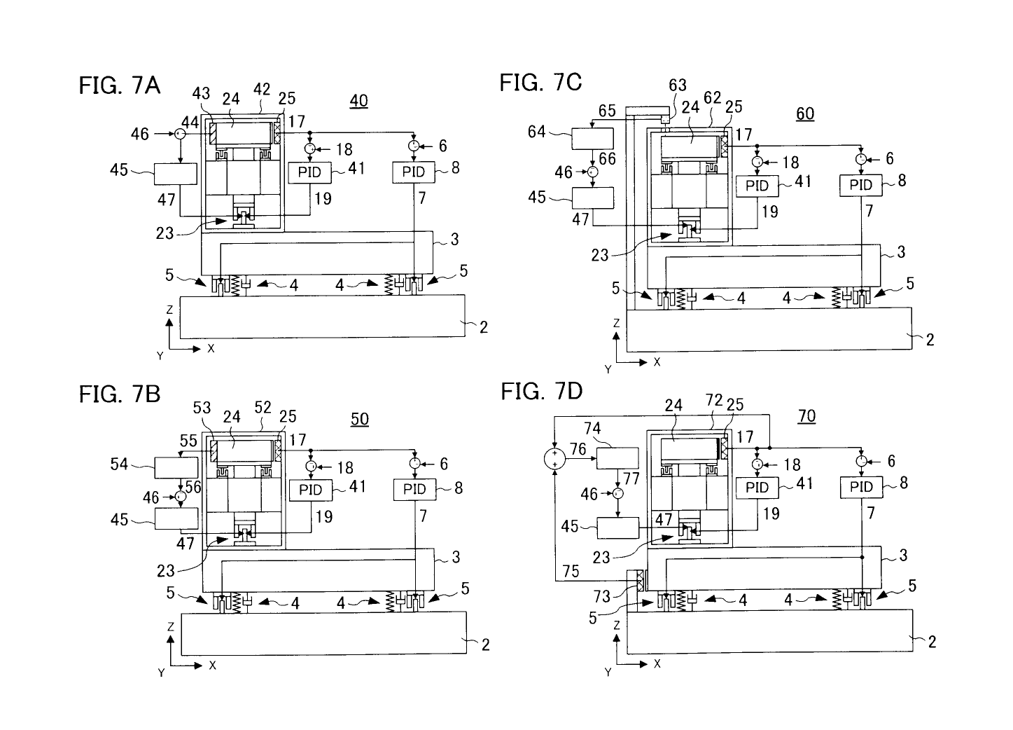

Next, a description will be given of a vibration isolation device according to a second embodiment of the present invention. FIG. 7A is a schematic view illustrating the configuration of a vibration isolation device according to the present embodiment. A vibration isolation device 40 of the present embodiment includes a reference body system 42 employing a PID compensator (second compensator) 41 instead of the compensator 26 that serves as the PD compensator of the reference body system 20 according to the first embodiment. Furthermore, the reference body system 42 includes a velocity sensor (second measuring unit) 43 that measures the velocity of the reference body 24 with respect to an absolute space. As shown in FIG. 7A, the velocity sensor 43 is arranged, for example, on the side surface of the reference body 24. In this case, a control system (velocity feedback control system) further feedback-controls the velocity of the reference body 24 relative to an absolute space via a compensator (third compensator) 45 based on the velocity information 44 obtained from the velocity sensor 43. The compensator 45 calculates a drive signal 47 to be sent to the actuator 23 based on the velocity information 44 and a preset target value 46. At this time, the control device applies the proportional gain Cᵣ₂ to the compensator 45.

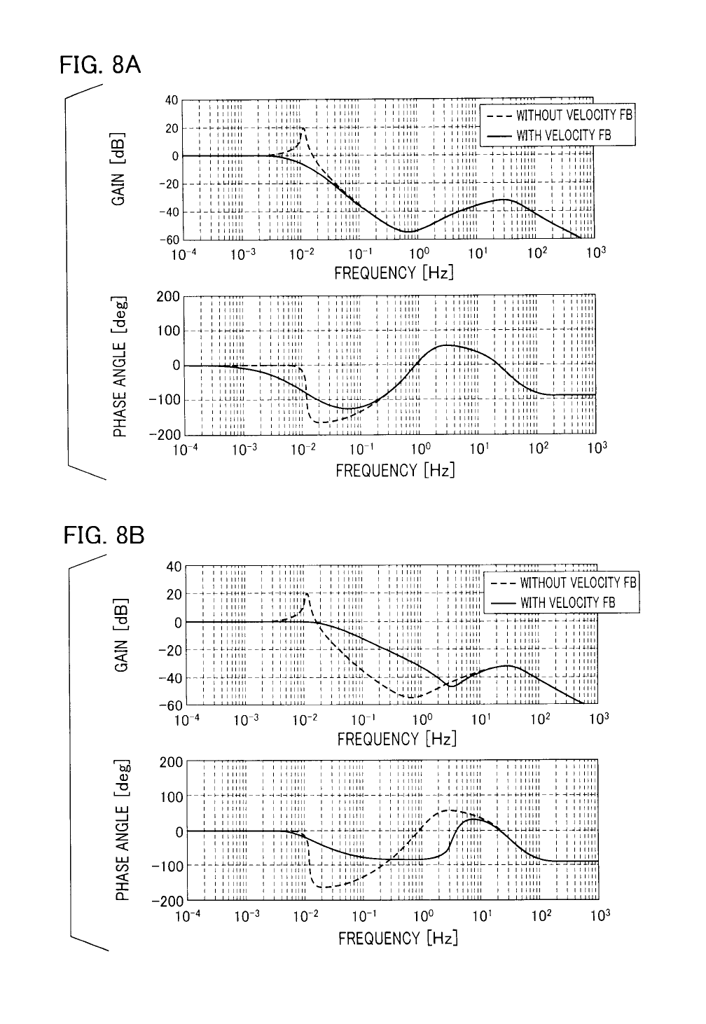

Next, a case where a PID compensator 41 is employed for the reference body system 42 and the velocity of the reference body 24 relative to an absolute space is feedback-controlled is compared to another case where a PID compensator 41 is employed for the same and the velocity of the reference body 24 relative to an absolute space is not feedback-controlled. FIG. 8A is a Bode plot diagram of the transfer function H₂ from the base 2 to the vibration isolation table 3 for each of the two cases. As shown in FIG. 8A, when a PID compensator is employed as in the present embodiment and a velocity feedback control is performed, a sharp peak around 0.01 Hz is damped, and thus, excellent vibration isolation performance is achieved even at a low frequency.

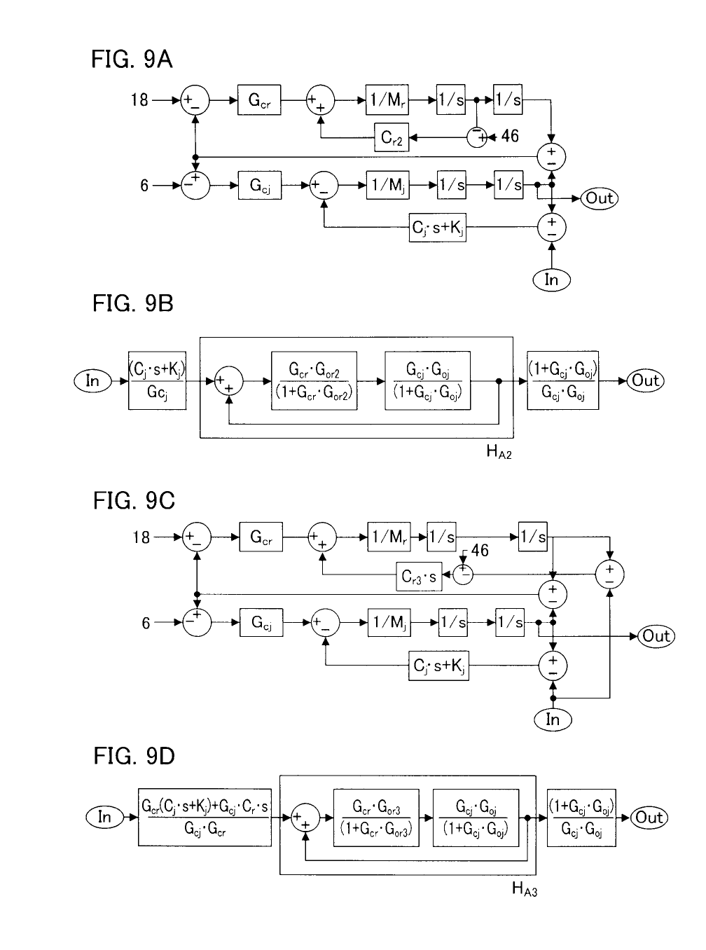

Next, the reasons why the aforementioned sharp peak is damped will be described below. FIG. 9A is a block diagram of the transfer function H₂ from the base 2 to the vibration isolation table 3 in this case. Firstly, the block diagram shown in FIG. 9A is transformed, the resulting block diagram is as shown in FIG. 9B. Here, when the block diagram enclosed within the frame shown in FIG. 9B is defined as the transfer function and is further transformed, the transfer function H is represented by Formula 20. Also, Gₒᵣ₂ is represented by Formula 21.

$$\begin{matrix}{H}_{A 2} = \frac{{G}_{cj} \cdot {G}_{oj} \cdot {G}_{cr} \cdot {G}_{{or}_{2}}}{1 + {G}_{cj} \cdot {G}_{oj} + {G}_{cr} \cdot {G}_{{or}_{2}}} & [ Formula 20 ] \\ {G}_{{or}_{2}} = \frac{1}{{M}_{r} \cdot {s}^{2} + {C}_{{r}_{2}} \cdot s} & [ Formula 21 ]\end{matrix}$$

Here, when Formulae 11 to 13 and Formula 21 are substituted for Formula 20, the transfer function H_{A2} is represented by Formula 22. Note that the small terms of M_{wj}×Cᵣ₂ and Kⱼ×Cᵣ₂ are ignored.

$${H}_{A 2} = \frac{\begin{matrix}{MW}_{j} \cdot {MW}_{r} \cdot {s}^{2} + {MW}_{j} \cdot {MW}_{r} ( {W}_{ij} - {W}_{ir} ) s + \\ {MW}_{j} \cdot {MW}_{r} \cdot {W}_{ij} \cdot {W}_{ir}\end{matrix}}{s \{ \begin{matrix}( {K}_{j} \cdot {M}_{r} + {MW}_{j} \cdot {M}_{r} ) {s}^{2} + {MW}_{j} \cdot {M}_{r} \cdot {W}_{ij} \cdot {s}^{2} + \\ ( {MW}_{r} \cdot {K}_{j} + {MW}_{j} \cdot {W}_{ij} \cdot {C}_{r 2} ) s + {MW}_{r} \cdot {K}_{j} \cdot {W}_{ir}\end{matrix} \}} \qquad [ Formula 22 ]$$

In this way, when the characteristic equation (Formula 22) of the transfer function of the present embodiment is compared with the characteristic equation (Formula 15) of the transfer function H_{Apid} of the first embodiment, only the first-order term of s within the double parentheses is changed. When iω is substituted into s, the first order term of s is a term including a complex number, and a term for determining the damping characteristic of the transfer function H_{A2}. Thus, if the velocity of the reference body 24 relative to an absolute space is feedback-controlled, a peak generated by the transfer function may be damped even when a PID compensator is employed for the compensator 41 of the reference body system 42.

### Third Embodiment

Next, a description will be given of a vibration isolation device according to a third embodiment of the present invention. FIG. 7B is a schematic view illustrating the configuration of a vibration isolation device according to the present embodiment. A vibration isolation device 50 of the present embodiment is modified from the reference body system 42 of the second embodiment, and includes a reference body system 52 employing the PID compensator 41. In addition, the reference body system 52 includes an acceleration sensor (second measuring unit) 53 and an integrator 54 instead of the velocity sensor 43 for measuring the velocity of the reference body 24 relative to an absolute space. In this case, the integrator 54 integrates acceleration information 55 obtained from the acceleration sensor 53 one time to thereby calculate velocity information 56. A control system feedback-controls the velocity of the reference body 24 relative to an absolute space via the compensator 45 based on the velocity information 56. The compensator 45 calculates a drive signal 47 to be sent to the actuator 23 based on the velocity information 56 and a preset target value 46. In this way, according to the present embodiment, the same effects as those of the second embodiment are obtained.

### Fourth Embodiment

Next, a description will be given of a vibration isolation device according to a fourth embodiment of the present invention. FIG. 7C is a schematic view illustrating the configuration of a vibration isolation device according to the present embodiment. A vibration isolation device 60 of the present embodiment is also modified from the reference body system 42 of the second embodiment, and includes a reference body system 62 employing the PID compensator 41. In addition, the reference body system 62 includes a position sensor 63 for measuring the displacement of the reference body 24 relative to the base 2, and a differentiator 64. In this case, the differentiator 64 differentiates position information 65 obtained from the position sensor 63 one time to thereby calculate velocity information 66. A control system feedback-controls the velocity of the reference body 24 relative to the base 2 via the compensator 45 based on the velocity information 66. As in the second embodiment, the compensator 45 calculates a drive signal 47 to be sent to the actuator 23 based on the velocity information 66 and a preset target value 46. At this time, the control device applies the proportional gain to the compensator 45.

Next, a case where a PID compensator 41 is employed for the reference body system 62 and the velocity of the reference body 24 relative to the base 2 is feedback-controlled is compared to another case where a PID compensator 41 is employed for the same and the velocity of the reference body 24 relative to the base 2 is not feedback-controlled. FIG. 8B is a Bode plot diagram of the transfer function H₃ from the base 2 to the vibration isolation table 3 for each of two cases. As shown in FIG. 8B, when a PID compensator is employed as in the present embodiment and a velocity feedback control is performed, a sharp peak around 0.01 Hz is damped, and thus excellent vibration isolation performance is achieved even at a low frequency.

Next, the reasons why the aforementioned sharp peak is damped will be described below. FIG. 9C is a block diagram of the transfer function H from the base 2 to the vibration isolation table 3 in this case. Firstly, when the block diagram shown in FIG. 9C is transformed, the resulting block diagram is as shown in FIG. 9D. Here, when the block diagram enclosed within the frame shown in FIG. 9D is defined as the transfer function H_{A3}, and is further transformed, the transfer function H_{A3} is represented by Formula 23. Also, Gₒᵣ₃ is represented by Formula 24.

$$\begin{matrix}{H}_{A 3} = \frac{{G}_{cj} \cdot {G}_{oj} \cdot {G}_{cr} \cdot {G}_{{or}_{3}}}{1 + {G}_{cj} \cdot {G}_{oj} + {G}_{cr} \cdot {G}_{{or}_{3}}} & [ Formula 23 ] \\ {G}_{{or}_{3}} = \frac{1}{{M}_{r} \cdot {s}^{2} + {C}_{r 3} \cdot s} & [ Formula 24 ]\end{matrix}$$

Here, when Formulae 11 to 13 and Formula 24 are substituted for Formula 23, the transfer function H_{A3} is represented by Formula 25. Note that the small terms of M_{wj}×Cᵣ₃ and Kⱼ×Cᵣ₃ are ignored.

$${H}_{A 3} = \frac{\begin{matrix}{MW}_{j} \cdot {MW}_{r} \cdot {s}^{2} + {MW}_{j} \cdot {MW}_{r} ( {W}_{ij} + {W}_{ir} ) s + \\ {MW}_{i} \cdot {MW}_{r} \cdot {W}_{ij} \cdot {W}_{ir}\end{matrix}}{s \{ \begin{matrix}( {K}_{j} \cdot {M}_{r} + {MW}_{j} \cdot {M}_{r} ) {s}^{3} + {MW}_{j} \cdot {M}_{r} \cdot {W}_{ij} \cdot {s}^{2} + \\ ( {MW}_{r} \cdot {K}_{j} + {MW}_{j} \cdot {W}_{ij} \cdot {C}_{r 3} ) s + {MW}_{r} \cdot {K}_{j} \cdot {W}_{ir}\end{matrix} \}} \qquad [ Formula 25 ]$$

In this way, when the characteristic equation (Formula 25) of the transfer function of the present embodiment is compared with the characteristic equation (Formula 15) of the transfer function H_{Apid} of the first embodiment, only the first-order term of s within the double parentheses is changed. When iω is substituted into s, the first-order term of s is a term including a complex number, and a term for determining the damping characteristic of the transfer function H_{A3}. Thus, if the velocity of the reference body 24 relative to the base 2 is feedback-controlled, a peak generated by the transfer function may be damped even when a PID compensator is employed for the compensator 41 of the reference body system 62.

### Fifth Embodiment

Next, a description will be given of a vibration isolation device according to a fifth embodiment of the present invention. FIG. 7D is a schematic view illustrating the configuration of a vibration isolation device according to the present embodiment. A vibration isolation device 70 of the present embodiment is modified from the reference body system 42 of the fourth embodiment, and includes a reference body system 72 employing the PID compensator 41. In addition, the reference body system 72 includes a position sensor (third measuring device) 73 for measuring the relative position between the vibration isolation table 3 on which the reference body 24 is disposed and the base 2, and a differentiator 74. The position sensor 73 is disposed either on the base 2 or on the vibration isolation table 3. In this case, a control system calculates a sum of the position information 17 about the position sensor 25 provided in the reference body system 72 and the position information 75 about the position sensor 73 for measuring the relative position between the base 2 and the vibration isolation table 3 to thereby determine the relative position information 76 about the reference body 24 relative to the base 2. The differentiator 74 differentiates the relative position information 76 one time to thereby calculate relative velocity information 77. A control system feedback-controls the velocity of the reference body 24 relative to the base 2 via the compensator 45 based on the relative velocity information 77. As in the second embodiment, the compensator 45 calculates a drive signal 47 to be sent to the actuator 23 based on the relative velocity information 77 and a preset target value 46. At this time, the control system applies the proportional gain Cᵣ₃ to the compensator 45. In this way, according to the present embodiment, the same effects as those of the fourth embodiment are obtained.

Here, with reference to the Bode plot diagrams shown in FIGS. 8A and 8B, the transfer function of the vibration isolation device according to the second and third embodiments shown in FIG. 8A is compared with that of the vibration isolation device according to the fourth and fifth embodiments shown in FIG. 8B. In comparison to the transfer function shown in FIG. 8A, the vibration isolation performance of the transfer function shown in FIG. 8B deteriorates in the range of 0.01 to 1 Hz. Thus, in theory, a vibration isolation device exhibiting an excellent vibration isolation performance may be provided when the second and the third embodiments are employed. However, when the second and the third embodiments are employed, a vibration isolation performance depends on the performance of the velocity sensor 43 and the acceleration sensor 53. In general, it is highly probable that the velocity sensor and the acceleration sensor have a measurement error in the low frequency range. On the other hand, in the fourth and fifth embodiments, since velocity information is calculated by differentiating position information one time, velocity information exhibiting excellent measurement accuracy in the low frequency range may be obtained.

### Sixth Embodiment

Next, a description will he given of a vibration isolation device according to a sixth embodiment of the present invention. In the vibration isolation device of the present embodiment, a PID compensator in which a high pass filter serving as a filter circuit is added is employed as the compensator of the reference body system. As described with reference to the Bode plot diagram shown in FIG. 3 according to the first embodiment, a sharp peak occurs in the low frequency range when a PID compensator is employed as the compensator of the reference body system. Thus, in the present embodiment, a high pass filter is added between the break frequency Wᵢᵣ of the integrator provided in the PID compensator and the frequency at which a sharp peak occurs such that the integrator provided in the PID compensator does not work at the frequency band at which a sharp peak occurs.

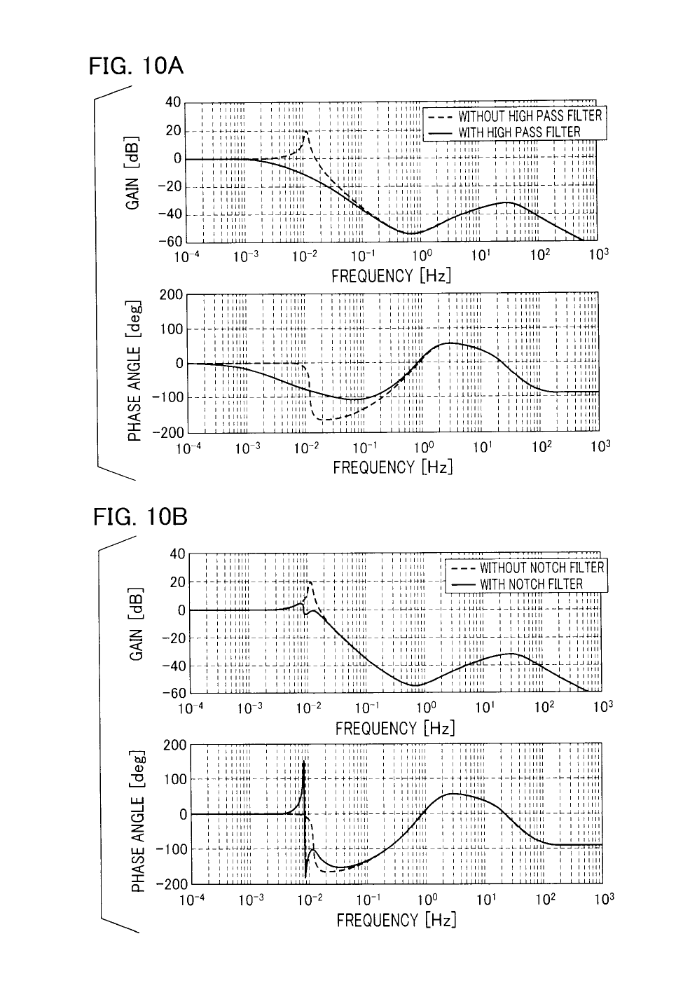

Next, a case where a bypass filter is added to the PID compensator of the reference body system is compared to another case where a bypass filter is not added thereto. FIG. 10A is a Bode plot diagram of the transfer function H₄ from the base 2 to the vibration isolation table 3 for each of two cases. As shown in FIG. 10A, when a high pass filter is added to a PID compensator as in the present embodiment, a sharp peak around 0.01 Hz is damped, and thus, excellent vibration isolation performance is achieved even at a low frequency. In this case, the transfer function H₄ of a PID compensator to which a high pass filter is added is represented by Formula 26. For example, as compared with the third embodiment, the break frequency Wₑᵣ of the high pass filter to he added needs to be smaller than the break frequency Wᵢᵣ of the integrator used in the vibration isolation device 50 and greater than the frequency of a sharp peak generated when a PID compensator is employed as the compensator 41.

$${M}_{r} \cdot {W}_{cr} \cdot {W}_{dr} ( 1 + \frac{s}{{W}_{dr}} ) ( 1 + \frac{{W}_{ir}}{s} ) \times ( \frac{s}{s + {W}_{cr}} ) \qquad [ Formula 26 ]$$

### Seventh Embodiment

Next, a description will be given of a vibration isolation device according to a seventh embodiment of the present invention. While, in the vibration isolation device of the sixth embodiment, a high pass filter is added to the PID compensator of the reference body system, in the present embodiment, a notch filter serving as a band-stop filter having a narrow blocking band instead of a high pass filter is added thereto. Likewise, a case where a notch filter is added to the PID compensator of the reference body system is compared to another case where a notch filter is not added thereto. FIG. 10B is a Bode plot diagram of the transfer function H₅ from the base 2 to the vibration isolation table 3 for each of two cases. As shown in FIG. 10B, when a notch filter is added to a PID compensator, a sharp peak around 0.01 Hz is also damped, and thus, excellent vibration isolation performance is achieved even at a low frequency.

### Eighth Embodiment

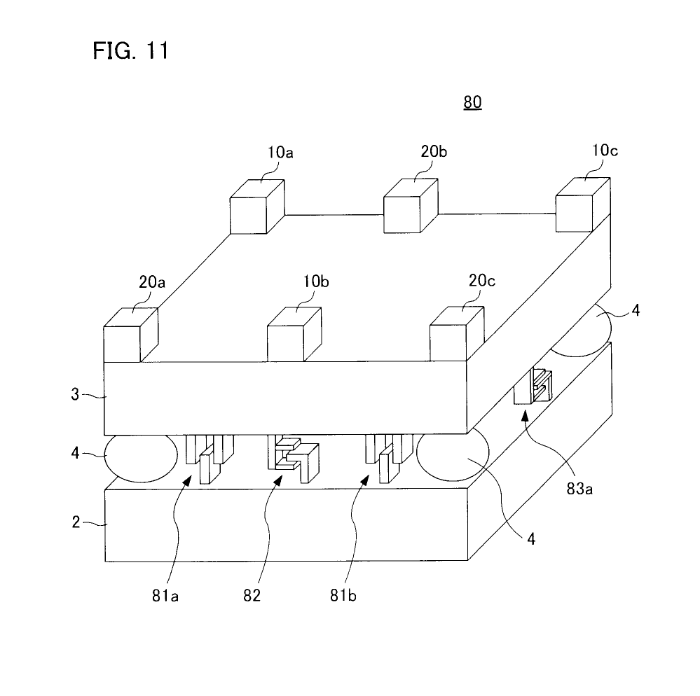

Next, a description will be given of a vibration isolation device according to an eighth embodiment of the present invention. FIG. 11 is a schematic view illustrating the configuration of the vibration isolation device of the present embodiment. In FIG. 11, the same elements as those in the aforementioned embodiments shown in the preceding figures are designated by the same reference numerals, and thus, the explanation thereof will be omitted. The vibration isolation device of the present embodiment isolates the vibration of the vibration isolation table 3 in the multi-axis directions by using at least six or more reference body systems employed in any one of the vibration isolation devices according to the first to seventh embodiments, more specifically, by using three or more reference bodies in the horizontal direction and three or more reference bodies in the vertical direction. For example, a vibration isolation device 80 shown in FIG. 11 includes three reference body systems 10 (10a to 10c) for the horizontal direction and three reference body systems 20 (20a to 20c) for the vertical direction on the vibration isolation table 3. Further, the vibration isolation device 80 includes three Z-axis drive actuators 81a to 81c for driving the vibration isolation table 3 in the six-axis direction, one X-axis drive actuator 82, and two Y-axis drive actuators 83a and 83b that are disposed between the base 2 and the vibration isolation table 3. In FIG. 11, the portion of the actuators is not shown.

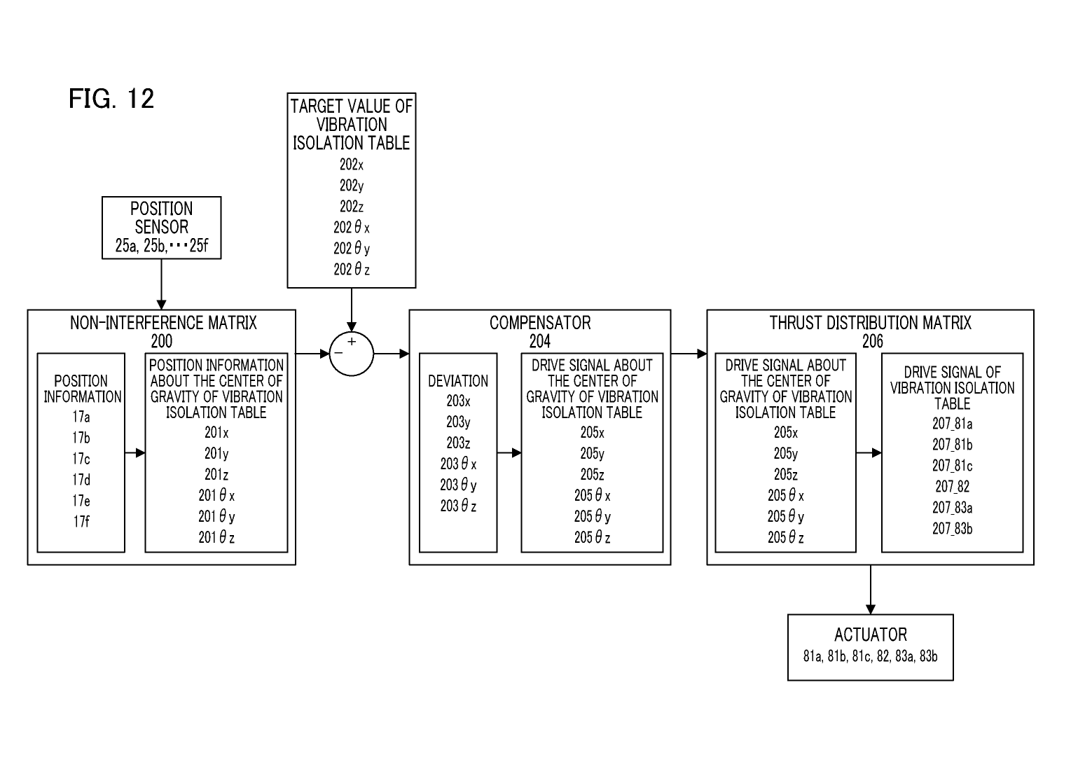

FIG. 12 is a block diagram illustrating a method for controlling a vibration isolation device 80. Firstly, a control device acquires position information 17 (17a to 17f) from six position sensors 25 (25a to 25f) disposed on six reference body systems 10a to 10c and 20a to 20c. Next, the control device converts the six-position information 17 into six axis position information 201 (201x, 201y, 201z, 201θx, 201θy, and 201θz) about the center of gravity of the vibration isolation table 3 by a non-interference matrix 200. Next, the control device calculates deviations 203 (203x, 203y, 203z, 203θx, 203θy, and 203θz) from the differences between six-position information 201 and preset target values 202 (202x, 202y, 202z, 202θx, 202θy, and 202θz). Next, the control device subjects these six deviations 203 to the compensator 204 to thereby determine six drive signals 205 (205x, 205y, 205z, 205θx, 205θy, and 205z) about the center of gravity of the vibration isolation table 3. Next, the drive signals 205 are converted into the drive signals 207 (207_81a, 207_81b, 207_81c, 207_82, 207_83a, and 207_83b) of the six actuators 81a to 81c, 82, 83a, and 83b using a thrust distribution matrix 206. Then, the actuators 81a to 81c, 82, 83a, and 83b drive the vibration isolation table 3 in the six-axis direction based on these six drive signals 207. In this way, according to the present embodiment, the vibration isolation table 3 may be isolated from vibration even at a low frequency with accuracy in the six-axis direction.

### Ninth Embodiment

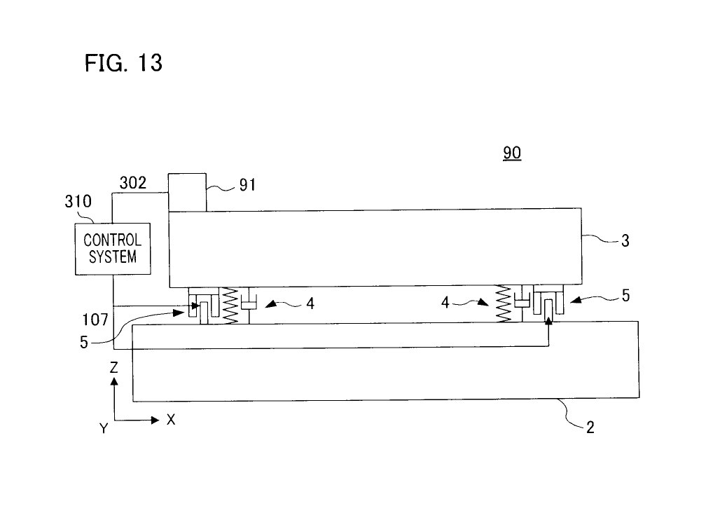

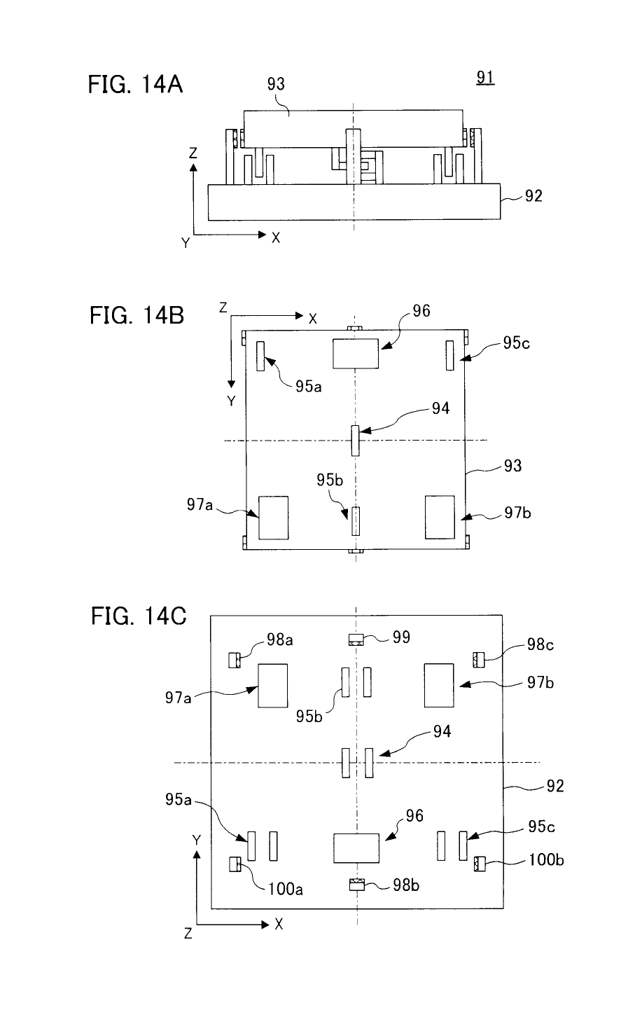

Next, a description will be given of a vibration isolation device according to a ninth embodiment of the present invention. FIG. 13 is a schematic view illustrating the configuration of the vibration isolation device of the present embodiment. In FIG. 13, the same elements as those in the aforementioned embodiments shown in the preceding figures are designated by the same reference numerals, and thus, the explanation thereof will be omitted. A vibration isolation device 90 of the present embodiment employs a reference body system 91 that is capable of performing six-axis measurement as shown in FIG. 13 as the reference body system disposed on the vibration isolation table 3, and isolates the vibration of the vibration isolation table 3 in the six-axis direction. FIGS. 14A to 14C are schematic diagrams illustrating the configuration of the reference body system 91. In particular, FIG. 14A is a side view of the reference body system 91, FIG. 14B is a bottom plan view of the reference body 93 facing the base 92, and FIG. 14C is a top plan view of the base 92 facing the reference body 93. The reference body system 91 includes one own-weight compensation unit 94, six actuators, and six displacement sensors, all of which are disposed between the base 92 and the reference body 93. The own-weight compensation unit 94 is disposed at the center of the reference body 93, and supports the reference body 93 from the base 92 by imparting a force balancing the own-weight of the reference body 93 to thereby compensate the own-weight of the reference body 93. The own-weight compensation unit 94 may be provided in plurality. The six actuators are constituted by three Z-axis drive actuators 95a to 95c, one X-axis drive actuator 96, and two Y-axis drive actuators 97a and 97b in order to drive the reference body 93 in six axes with respect to the base 92. Six displacement sensors are measuring units configured to measure the position of the reference body 93 relative to the base 92 in the six-axis direction. The six displacement sensors are constituted by three displacement sensors 98a to 98c for the Z-axis direction, one displacement sensor 99 for the X-axis direction, and two displacement sensors 100a and 100b for the Y-axis direction.

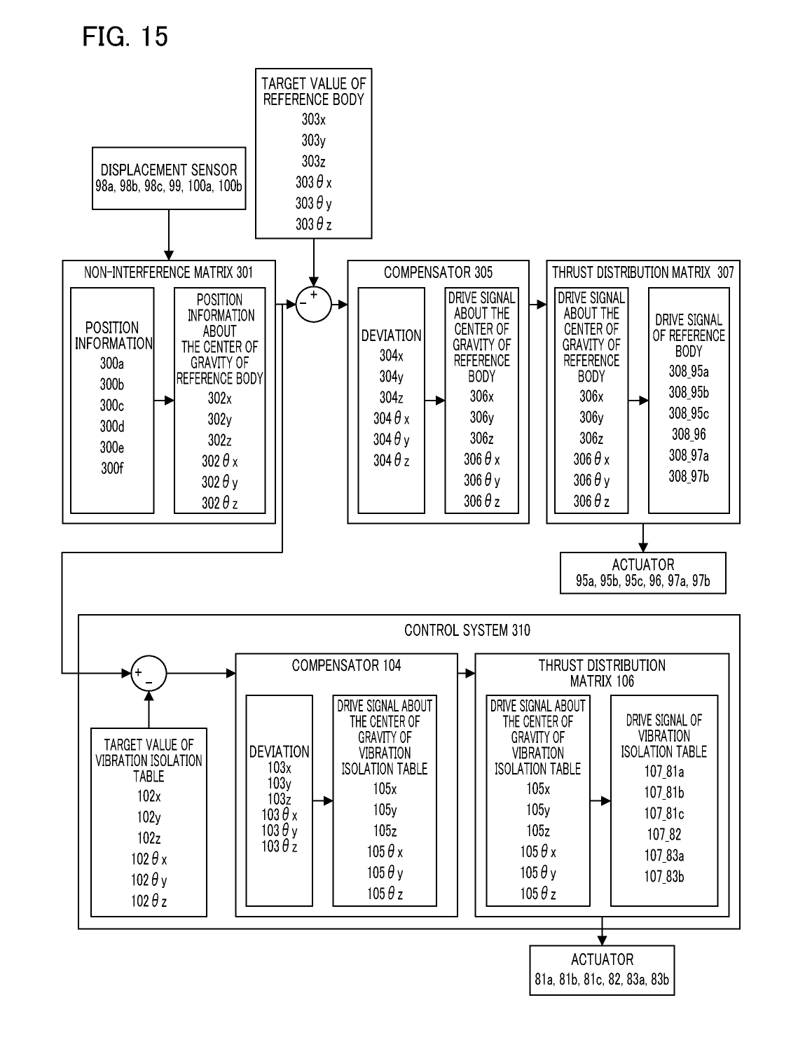

FIG. 15 is a block diagram illustrating a method for controlling the vibration isolation device 90. Firstly, a control device acquires position information 300 (300a to 300f) from six displacement sensors described above. Next, the control device converts the six-position information 300 into six-axis position information 302 (302x, 302y, 302z, 302θx, 302θy, and 302θz) about the center of gravity of the reference body 93 by a non-interference matrix 301. Next, the control device calculates deviations 304 (304x, 304y, 304z, 304θx, 304θy, and 304θz) from the differences between the six-position information 302 and preset target values 303 (303x, 303y, 303z, 303θx, 303θy, and 303θz). Next, the control device subjects these six deviations 304 to the compensator 305 to thereby determine six drive signals 306 (306x, 306y, 306z, 306θx, 306θy, and 306θz) about the center of gravity of the reference body 93. In this case, while a PD compensator is employed as the compensator 305, any one of the compensators shown in the aforementioned embodiments may also be employed. Next, the drive signals 306 are converted into the drive signals 308 (308_95a, 308_95b, 308_95c, 308_96, 308_97a, and 308_97b) of the six actuators 95a to 95c, 96, 97a, and 97b using a thrust distribution matrix 307. Then, the actuators 95a to 95c, 96, 97a, and 97b drive the reference body 93 in the six-axis direction based on these six drive signals 308.

Furthermore, the control device executes control similar to that in the eighth embodiment using another control system 310 disposed therein. In other words, firstly, a control system 310 calculates six deviations 103 from the differences between six-position information 302 about the center of gravity of the reference body 93 and preset target values 102 of the vibration isolation table 3. Next, the control system 310 subjects these six deviations 103 to the compensator 104 to thereby determine six drive signals 105 about the center of gravity of the vibration isolation table 3. Next, these six drive signals 105 are converted into the drive signals 107 of the six actuators 81a to 81c, 82, 83a, and 83b using a thrust distribution matrix 106. Then, the actuators 81a to 81c, 82, 83a, and 83b drive the vibration isolation table 3 in the six-axis direction based on these six drive signals 107. In this way, according to the present embodiment, the vibration isolation table 3 may be isolated from vibration even at a low frequency with accuracy in the six-axis direction as in the eighth embodiment.

### (Exposure Apparatus)

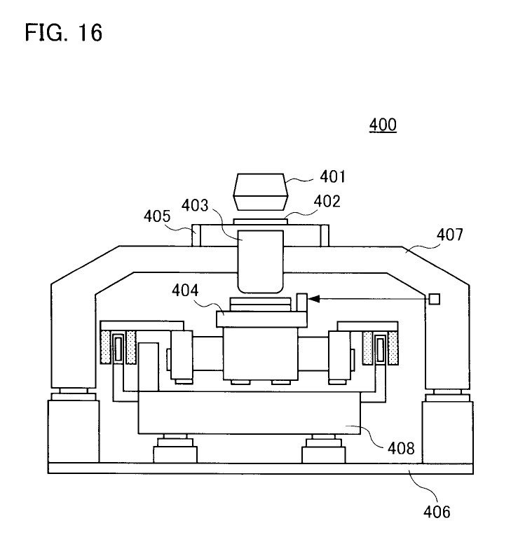

Next, a description will be given of an exposure apparatus employing the vibration isolation device of the present invention. FIG. 16 is a schematic view illustrating the configuration of an exposure apparatus according to the present embodiment. An exposure apparatus 400 includes an illumination optical system 401, a reticle stage 402 that holds a reticle, a projection optical system 403, and a substrate stage 404 that holds a substrate to be treated. The exposure apparatus 400 of the present embodiment is a scanning projection exposure apparatus that exposes the pattern formed on the reticle to a wafer, i.e., a substrate to be treated, employing a step-and-repeat system or a step-and-scan system. The illumination optical system 401 includes a light source unit (not shown), and is a device that illuminates the reticle. At the light source unit, the light source uses a laser, for example. Available lasers include an ArF excimer laser with a wavelength of about 193 nm, a KrF excimer laser with a wavelength of about 248 nm, an F2 excimer laser with a wavelength of about 157 nm, and the like. The reticle is, for example, an original plate made of quartz glass. The circuit pattern to be transferred is formed on the reticle. Also, the reticle stage 402 is a stage that is moveable in the x-y direction, and is a device that holds the reticle. The reticle stage 402 is held on a reticle stage base 405. The projection optical system 403 projects and exposes the pattern on the reticle, which has been illuminated with exposure light from the illumination optical system 401, onto the substrate with a predetermined magnification (e.g., 1/4). As the projection optical system 403, an optical system consisting only of a plurality of optical elements or an optical system (catadioptric optical system) consisting of a plurality of optical elements and at least one concave mirror can be employed. The reticle stage base 405 and the projection optical system 403 are supported by a lens barrel plate 407 including the vibration isolation device of the present invention on a floor (base ground surface) 406. A substrate (substrate to be treated) is an object to be processed such as a silicon wafer or the like. A photosensitizer (resist) is applied on the surface thereof. The substrate stage 404 is a stage that is movable in the X, Y, and Z directions. The substrate stage 404 is disposed on a stage plate 408 that is placed on the floor (base ground surface) 406. In the exposure apparatus 400, the diffracted light emitted from the reticle passes through the projection optical system 403 and is projected on the substrate. The substrate is in a conjugated relationship with the reticle. In the case of a scanning type projection exposure apparatus, the pattern of the reticle is transferred onto the substrate by scanning the reticle and the substrate. In the case of a stepper (step-and-repeat type exposure device), exposure is performed while the reticle and the substrate are held stationary. Here, the lens barrel plate 407 includes the vibration isolation device according to the aforementioned embodiments, and thus excellent vibration isolation performance is achieved even at a low frequency.

### (Device Manufacturing Method)

Next, a method of manufacturing a device (semiconductor device, liquid crystal display device, etc.) as an embodiment of the present invention is described. The semiconductor device is manufactured by a front-end process in which an integrated circuit is formed on a wafer, and a back-end process in which an integrated circuit chip is completed as a product from the integrated circuit on the wafer formed in the front-end process. The front-end process includes a step of exposing a wafer coated with a photoresist to light using the above-described exposure apparatus of the present invention, and a step of developing the exposed wafer. The back-end process includes an assembly step (dicing and bonding), and a packaging step (sealing). The liquid crystal display device is manufactured by a process in which transparent electrodes are formed. The process of forming a plurality of transparent electrodes includes a step of coating a glass substrate with a transparent conductive film deposited thereon with a photoresist, a step of exposing the glass substrate coated with the photoresist to light using the above-described exposure apparatus, and a step of developing the exposed glass substrate. The device manufacturing method of this embodiment has an advantage, as compared with a conventional device manufacturing method, in at least one of performance, quality, productivity and production cost of a device.

While the embodiments of the present invention have been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-184616 filed Aug. 20, 2010 which is hereby incorporated by reference herein in its entirety.

What is claimed is:

1. A vibration isolation device that isolates the vibration of an object to be isolated from vibration supported on a base, the vibration isolation device comprising:
a first position feedback control system comprising:
a reference body system that is fixed to the object to be isolated from vibration and includes a reference body;
a first driving unit that drives the object to be isolated from vibration with respect to the base; and
a first compensator that calculates a command value to the first driving unit based on position information obtained from the reference body system,
wherein the reference body system comprises:
a second position feedback control system comprising:
a second driving unit that drives the reference body with respect to the object to be isolated from vibration;
a first measuring unit that measures the position of the reference body relative to the object to be isolated from vibration; and
a second compensator that calculates a command value to the second driving unit based on position information obtained from the first measuring unit, and
wherein the second compensator is a PD compensator.

2. A vibration isolation device that isolates the vibration of an object to be isolated from vibration supported on a base, the vibration isolation device comprising:
a first position feedback control system comprising:
a reference body system that is fixed to the object to be isolated from vibration and includes a reference body;
a first driving unit that drives the object to be isolated from vibration with respect to the base; and
a first compensator that calculates a command value to the first driving unit based on position information obtained from the reference body system,
wherein the reference body system comprises:
a second position feedback control system comprising:
a second driving unit that drives the reference body with respect to the object to be isolated from vibration;
a first measuring unit that measures the position of the reference body relative to the object to be isolated from vibration; and
a second compensator that calculates a command value to the second driving unit based on position information obtained from the first measuring unit, and
a velocity feedback control system comprising:
a second measuring unit that acquires velocity information about the reference body; and
a third compensator that calculates a command value to the second driving unit based on velocity information obtained from the second measuring unit, and
wherein the second compensator is a PID compensator.

3. The vibration isolation device according to claim 2, wherein the second measuring unit is a velocity sensor that measures the velocity of the reference body relative to an absolute space.

4. The vibration isolation device according to claim 2, wherein the reference body system further comprises an integrator, and the second measuring unit is an acceleration sensor that measures the acceleration of the reference body relative to an absolute space, and
wherein the integrator acquires the velocity information by integrating the acceleration information obtained from the second measuring unit one time.

5. The vibration isolation device according to claim 2, wherein the reference body system further comprises a differentiator, and the second measuring unit is a position sensor that measures the position of the reference body relative to the base, and
wherein the differentiator acquires the velocity information by differentiating the position information obtained from the second measuring unit one time.

6. The vibration isolation device according to claim 2, wherein the reference body system further comprises a differentiator, and the second measuring unit comprises the first measuring unit and a third measuring unit that measures the position of the object to be isolated from vibration relative to the base, and
wherein the third measuring unit is a position sensor that measures the position of the object to be isolated from vibration relative to the base, and the differentiator acquires the velocity information by differentiating a sum of the position information obtained from the first measuring unit and the third measuring unit one time.

7. A vibration isolation device that isolates the vibration of an object to be isolated from vibration supported on a base, the vibration isolation device comprising:
a first position feedback control system comprising:
a reference body system that is fixed to the object to be isolated from vibration and includes a reference body;
a first driving unit that drives the object to be isolated from vibration with respect to the base; and
a first compensator that calculates a command value to the first driving unit based on position information obtained from the reference body system,
wherein the reference body system comprises:
a second position feedback control system comprising:
a second driving unit that drives the reference body with respect to the object to be isolated from vibration;
a first measuring unit that measures the position of the reference body relative to the object to be isolated from vibration; and
a second compensator that calculates a command value to the second driving unit based on position information obtained from the first measuring unit, and
wherein the second compensator is a PID compensator to which a high pass filter having a smaller break frequency than that of an integrator provided in the PID compensator or a notch filter is added.

8. An exposure apparatus for exposing a substrate to transfer a pattern thereon, the exposure apparatus comprising:
the vibration isolation device according to claim 1.

9. An exposure apparatus for exposing a substrate to transfer a pattern thereon, the exposure apparatus comprising:
the vibration isolation device according to claim 2.

10. An exposure apparatus for exposing a substrate to transfer a pattern thereon, the exposure apparatus comprising:
the vibration isolation device according to claim 7.

11. A device manufacturing method comprising:
exposing a substrate using the exposure apparatus according to claim 8; and
developing the exposed substrate.

12. A device manufacturing method comprising:
exposing a substrate using the exposure apparatus according to claim 9; and
developing the exposed substrate.

13. A device manufacturing method comprising:
exposing a substrate using the exposure apparatus according to claim 10; and
developing the exposed substrate.
